(19) United States
(12) Patent Application Publication
(10) Pub. No.: US 2005/0073021 A1
(43) Pub. Date: Apr. 7, 2005

(54) Selective etch shallow trench isolation barrier integrated circuit chip and fabrication method

(76) Inventors: Calvin Gabriel, Cupertino, CA (US); Edward Yeh, San Jose, CA (US)

Correspondence Address: PHILIPS ELECTRONICS NORTH AMERICA CORPORATION;INTELLECTUAL PROPERTY & STANDARDS, 1109 MCKAY DRIVE, M/S-41SJ, SAN JOSE, CA, 95131, US

(21) Appl. No.: 10/603,358

(22) Filed: May 10, 2004

Related U.S. Application Data
(62) Division of application No. 09/492,737, filed on Jan. 27, 2000, now abandoned.

(51) Int. Cl. H01L 29/00

(52) U.S. Cl. 257/510

(57) ABSTRACT

The selective etch shallow trench isolation barrier integrated circuit fabrication system and method of the present invention minimizes the layers required to implement a shallow trench isolation barrier in an integrated circuit. A selective etch shallow trench isolation barrier integrated circuit in which a selective etch shallow trench isolation barrier is adjacent to an intermetal dielectric layer. Etching space in the intermetal dielectric layer for a contact plug is performed in a single film layer etch step. The selective etch shallow trench isolation barrier includes selective etch isolation material able to both withstand etching processes directed toward the insulation layer (e.g., to create a space for a contact plug) and facilitate isolation of devices from outside electrical influences. A present invention selective etch shallow trench isolation barrier integrated circuit does not require a shallow trench isolation barrier etch stop layer.

The present invention relates to the field of integrated circuit design and semiconductor chip fabrication. More particularly, the present invention relates to an efficient and effective system and method for fabricating a self aligned contact in an integrated circuit (IC).

### BACKGROUND OF THE INVENTION

Electronic systems and circuits have made a significant contribution towards the advancement of modern society and are utilized in a number of applications to achieve advantageous results. Electronic technologies such as digital computers, calculators, audio devices, video equipment, and telephone systems have facilitated increased productivity and reduced costs in analyzing and communicating data, ideas and trends in most areas of business, science, education and entertainment. Frequently, electronic systems designed to provide these results include integrated circuits. Traditionally, integrated circuits are manufactured in multistep processes that expend significant time performing sequential steps that consume expensive resources.

Integrated circuit manufacturing often includes lithographic processes in which a shallow trench is formed on a wafer made of semiconducting material, such as silicon (Si). A layer of a silicon oxide is deposited on the wafer followed by a layer of silicon nitride on top of the silicon oxide. The wafer is then coated with photoresist, exposed to the desired trench isolation pattern and the exposed photoresist is developed away. Silicon nitride in the open areas is plasma etched away and followed by the silicon oxide under the open areas stopping on the silicon semiconducting material. Then the silicon semiconducting material below the openings in the silicon oxide and silicon nitride is plasma etched to form a shallow trench. The trench is then usually filled oxide material. The wafer topography is then flattened in a chemical mechanical polishing (CMP) process leaving the filled trench and the nitride. The remaining nitride is stripped away. Gates and spacers are then formed followed by a first layer of insulation.

Traditionally a first layer of insulation is formed by depositing an intermetal layer (or interlayer) of dielectric material. The intermetal dielectric layer usually comprises a nitride layer capped with an oxide layer deposited in two deposition steps. The wafer topography is then flattened in a CMP process. The wafer is then coated with a photoresist layer, the desired contact hole pattern is exposed and the exposed photoresist is developed away. Contact holes are then plasma etched in the interlayer dielectric material. Typically this requires two etch steps or etching processes, one for the oxide and one for the nitride. Then the remaining photoresist is stripped. Conductive material is deposited in the contact holes which is followed by a plasma etch or CMP of the conductive material to form conductive plugs inside the contacts. Then the first metalization layer is formed.

FIG. 1 is an illustration of a prior art integrated circuit 100. Integrated circuit 100 comprises a device layer 105 and an intermetal dielectric layer 107. Device layer 105 comprises silicon semiconductor material 111, oxide shallow trench isolation barrier 150, nitride spacer 170, gate 140, shallow trench barrier etch stop layer 130. Intermetal dielectric layer 107 comprises dielectric material 120 and contact plugs 911 and 192 Device layer 105 is coupled to intermetal dielectric layer 107. Shallow trench isolation barrier 113 isolates gate 140 from another gate or device (not shown).

The components of integrated circuit 100, such as gate 140, dielectric nitride spacer 170, shallow trench isolation barrier 150, and contact holes 191, are fabricated by a lithographic process. Theoretically, the walls of isolation trench 150 are vertical but in reality the oxide tends to want to go in all directions and so it starts to spread out into local oxidation region 155 of isolation trench 150. Traditionally, shallow trenches are filled with oxide. Thus a shallow trench etch stop layer of silicon nitride (“nitride”) is deposited over the wafer surface to prevent etching of an oxide layer deposited on top of the shallow trench barrier etch stop layer from affecting the oxide in the shallow trench. Contact plugs 191 and 192 are etched in the oxide layer and the shallow trench barrier etch stop layer.

A multistep conventional self-aligned contact (“contact”) plasma etch is utilized to remove the oxide and nitride to form contact holes that are filled with conductive material to form contact plugs 191 and 192. The oxide occupying volume 195 and 198 is etched away in the first etch step to form contact holes. For example a typical oxide removal etch step comprises Ar, CF₄, CHF₃, CO, and/or C₄F₈. The first etch stops at the shallow trench barrier etch stop layer. The second etch step is utilized to remove nitride (e.g., from volume 197) to form a space in the nitride shallow trench barrier etch stop layer for the desired contact hole. For example, the second step includes an etch comprising Ar, CF₄, CHF₃, C₂F₆, SP₆ and/or O₂ utilized to etch the nitride, stopping on the silicide and oxide of oxidation region 155. The second etch process does not substantially etch the oxide in shallow trench oxidation region 155. A conduction material is deposited in the contact holes to form contact plugs 191 and 492.

Shallow trench barrier etch stop layer 130 acts as stop of the oxide etch and is required to prevent problems associated with self aligning contacts and isolation trenches comprising local oxidation regions. In advanced integrated circuits, devices are squeezed very close together and reducing the space between them is often beyond the ability of photolithography alignment to accurately define a contact so that it does not interfere with other components. For example, the space between the gate 140 and the shallow trench isolation barrier 150 is too small for the etching process to properly etch without nitride shallow trench barrier etch stop layer 130. Thus, nitride shallow trench barrier etch stop layer 130 is required in traditional integrated circuits to act as an etch stop preventing etching from removing oxidation region 155 “overlapping” underneath the space of contact plug 191. If nitride barrier layer was not included in device layer 105, during the oxidation etch step to remove oxide from volume 195 the etching would also remove oxide from oxidation region 155. When a conducting material is deposited in contact plug 191 it would also fill the etched oxidation region 155, resulting in conduction through an isolation trench. Conducting electricity through the isolation trench defeats the purpose of the trench and may result in detrimental side effects such as short circuits.

Fabricating a shallow trench barrier etch stop layer consumes expensive resources and valuable process time. Integrated circuit manufacturing processes (e.g., photolithography etching, CMP, etc.) utilized to add layer to a chip are expensive and each layer adds to the overall cost. Adding a shallow trench barrier etch stop layer is often particularly expensive because usually additional process steps are required to etch or remove a portion of the shallow trench barrier etch stop layer. For example, etching a volume for contact plug 191 requires two separate etching steps, one to etch oxide from region 195 of oxide layer 120 and one to etch nitride from region 197 of shallow trench barrier etch stop layer 130. Further complicating integrated circuit fabrication processes are concerns that deposition and etching of a layer increases the probability of problems (e.g., etch stop, contamination, alignment errors, etc.) occurring.

What is required is a fabrication system and method that minimizes the layers required to implement a shallow trench isolation barrier in an integrated circuit. The system and method should facilitate the reduction of inappropriate or unplanned conduction of electricity. The system and method should also facilitate the reduction of expenses and time required to implement an integrated circuit isolation trench.

### SUMMARY OF THE INVENTION

The integrated circuit fabrication system and method of the present invention minimizes the layers required to implement a shallow trench isolation barrier in an IC. The system and method facilitates the reduction of inappropriate or unplanned conduction of electricity by providing effective capacitive isolation. The system and method also facilitates the reduction of expenses and time required to implement an integrated circuit isolation trench by utilizing a selective etch shallow trench isolation barrier system and method.

In one embodiment of the present invention etching space in the intermetal dielectric layer for a contact plug is performed in a single etch step. In one exemplary embodiment of the present invention a selective etch shallow trench isolation barrier is adjacent to art intermetal dielectric layer. The selective etch shallow trench isolation barrier includes selective etch isolation material able to both withstand etching processes directed toward the intermetal dielectric layer (e.g., to create a space for a contact plug) and facilitate isolation of devices from outside electrical influences. In one embodiment of the present invention the intermetal dielectric layer includes oxide and a selective etch shallow trench isolation barrier includes nitride; A present invention selective etch shallow trench isolation barrier integrated circuit does not require a shallow trench isolation barrier etch stop layer.

### BRIEF DESCRIPTION OF DRAWINGS

FIG. 1 is an illustration of a prior art integrated circuit.

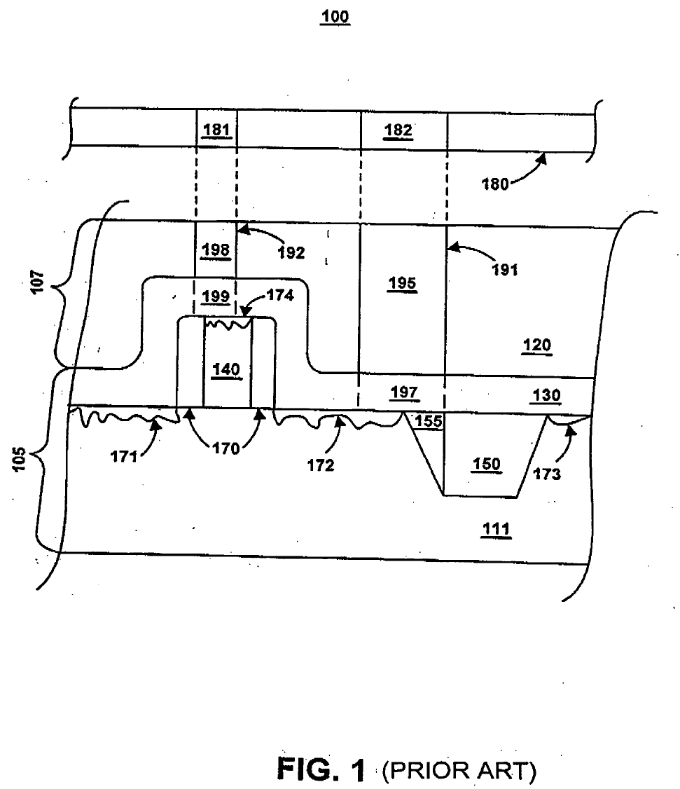

FIG. 2 is an illustration of a selective etch shallow trench isolation barrier integrated circuit, one embodiment of the present invention.

FIG. 3 is a flow chart of a selective etch material shallow trench isolation barrier integrated circuit chip fabrication process, one embodiment of the present invention.

### DETAILED DESCRIPTION OF THE INVENTION

Reference will now be made in detail to the preferred embodiments of the invention, a selective etch shallow trench isolation barrier integrated circuit and fabrication process, examples of which are illustrated in the accompanying drawings. While the invention will be described in conjunction with the preferred embodiments, it will be understood that they are not intended to limit the invention to these embodiments. On the contrary, the invention is intended to cover alternatives, modifications and equivalents, which may be included within the spirit and scope of the invention as defined by the appended claims. Furthermore, in the following detailed description of the present invention, numerous specific details are set forth in order to provide a thorough understanding of the present invention. However, it will be obvious to one ordinarily skilled in the an that the present invention may be practiced without these specific details. In other instances, well known methods, procedures, components, and circuits have not been described in detail as not to unnecessarily obscure aspects of the current invention.

The system and method of the present invention provides a selective etch shallow trench isolation barrier in an integrated circuit chip without a shallow trench barrier etch stop layer. The selective etch isolation material included in the selective etch shallow trench isolation barrier has a different selective etch rate than an adjacent intermetal dielectric layer above (e.g., an intermetal oxide layer). The different relative etch rate characteristics of the selective etch shallow trench isolation barrier enables a contact hole to be etched in the intermetal dielectric layer in a single film layer etch step. The selective etch isolation material resists etching processes directed at the adjacent intermetal layer without the need for an etch stop barrier layer. The selective etch isolation material included in the selective etch shallow trench isolation barrier also has a dielectric constant sufficient to provide isolation of components on opposite sides of the selective etch shallow trench isolation barrier.

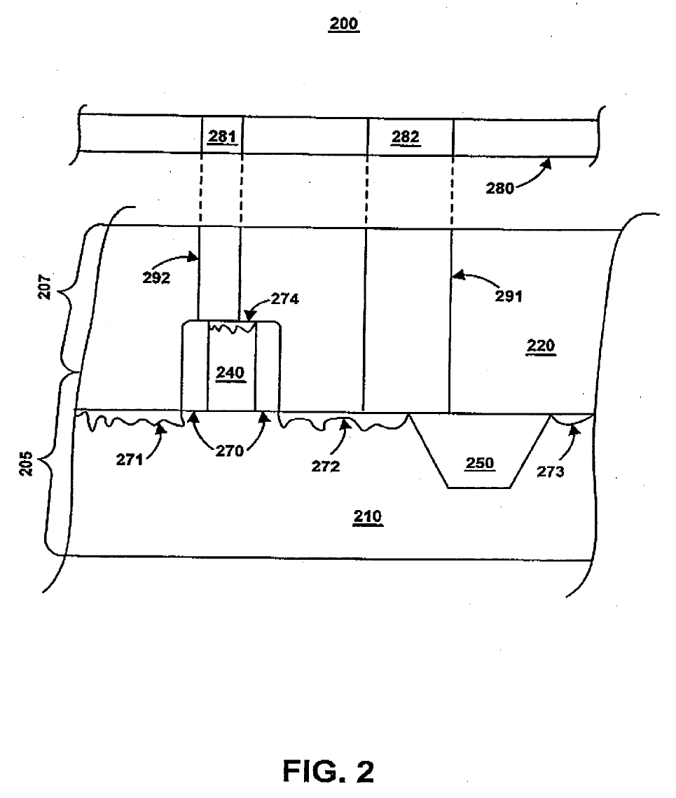

FIG. 2 is an illustration of a selective etch shallow trench isolation barrier integrated circuit 200, one embodiment of the present invention. Selective etch shallow trench isolation barrier integrated circuit 200 comprises a device layer 205 and an intermetal dielectric layer 207. Device layer 205 comprises silicon semiconducting material 210, selective etch shallow trench isolation barrier 250, nitride spacer 270, transistor gate 240, and silicide sections 271 through 274. Intermetal dielectric layer 207 comprises dielectric material 220 and contact plugs 291 and 292. Device layer 205 is coupled to intermetal dielectric layer 207. Transistor gate 240 is adapted to control electrical signal flow. Intermetal dielectric layer is adapted to insulate the transistor from other layers and is coupled to transistor gate 240, selective etch shallow trench isolation barrier 250 and contact plugs 291. Contact plugs 291 and 291 are adapted to conduct electricity.

The components of selective etch shallow trench isolation barrier integrated circuit 200, such as selective etch shallow trench isolation barrier 250, nitride spacer 270, and transistor gate 240, are fabricated by depositing materials of differing electrical characteristics on semiconducting material 210, In one example of selective etch shallow trench isolation barrier integrated circuit 200, semiconducting material 210 comprises silicon (Si) and transistor gate 240 comprises polysilicon or other conductor, intermetal dielectric layer 220 comprises oxide and contact plug 291 comprises tungsten or other conductor. In one embodiment of the present invention, selective etch shallow trench isolation barrier 250 comprises silicon nitride (Si₃N₄) or oxynitride (SiON).

Selective etch shallow trench isolation barrier integrated circuit 200 is a semiconductor chip that performs various operations in an electrical system. The device layer 205 forms electrical devices such as transistor switches that regulate signal propagation. Intermetal dielectric layer 207 provides insulation between conductive layers of shallow trench isolation barrier integrated circuit 200, with the exception of planned conductive paths for transmission of electrical signals between electrical devices in different layers. For example, contact plugs 291 and 292 provide appropriate and planned conductive paths between device layer 205 and another upper layer (not shown). Selective etch shallow trench isolation barrier 250 isolates gate 240 from another gate or device (not shown) on the opposite side of selective etch shallow trench isolation barrier 250.

Selective etch shallow trench isolation barrier 250 comprises selective etch isolation material that etches selective to other materials contacting it. A selective etch shallow trench isolation barrier material (e.g., nitride) includes etching characteristics that are significantly different (e.g., etches at a slower rate) than adjacent material. For example, etching a space for a contact plug in material (e.g., oxide) included in intermetal dielectric layer 220 is a one step etching process since there is no need for an etch stop barrier. The etching process to remove the interlayer dielectric material (e.g., oxide) from intermetal dielectric layer 220 etches down to the selective etch shallow trench isolation barrier 250 without adversely impacting selective etch shallow trench isolation barrier 250. Thus, there is no need for a shallow trench isolation barrier etch stop layer.

In addition to etching differently than adjacent material, isolation selective etch material included in selective etch shallow trench isolation barrier 250 facilitates reduced adverse electrical charge influence between components included in selective etch shallow trench isolation barrier integrated circuit 200. In one embodiment of the present invention, an isolation selective etch material (e.g., nitride) has a relatively high dielectric constant (e.g., k=6 to 7). In one embodiment of the present invention, a selective etch shallow trench isolation barrier 250 is utilized to isolate electrically floating devices included in selective etch shallow trench isolation barrier integrated circuit 200.

It should be appreciated that a selective etch shallow trench isolation barrier includes a variety of shapes and sizes. In one exemplary embodiment of the present invention, a selective etch shallow trench isolation barrier has rounded edges and in another embodiment a selective etch shallow trench isolation barrier has relatively sharp edges. It should also be appreciated that selective etch shallow trench isolation barriers are arranged in a variety of patterns and configurations throughout a selective etch shallow trench isolation barrier integrated circuit.

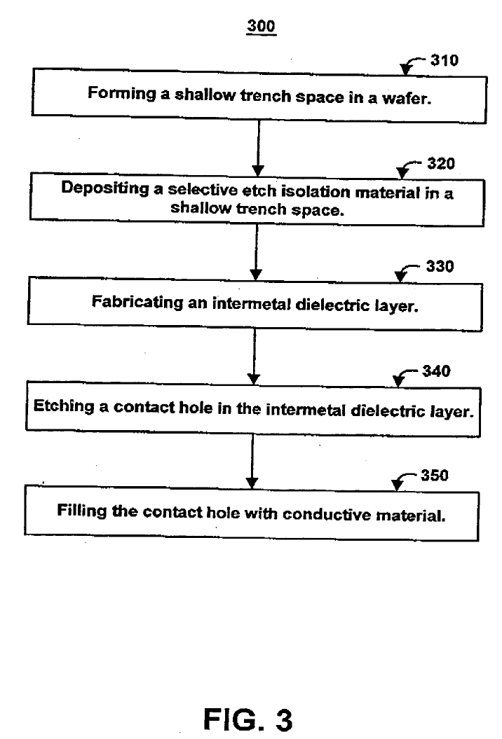

FIG. 3 is a flow chart of selective etch shallow trench isolation barrier integrated circuit chip fabrication process 300, one embodiment of the present invention. Selective etch shallow trench isolation barrier integrated circuit chip fabrication process 300, enables a shallow trench isolation barrier to be included in a semiconductor chip without a shallow trench etch stop layer. The selective etch shallow trench isolation barrier integrated circuit chip fabrication process 300 facilitates reduction of fabrication steps.

A shallow trench space is formed in a wafer in step 310 of selective etch shallow trench isolation barrier integrated circuit chip fabrication process 300. For example, a lithographic process is utilized in which a shallow trench is formed on a wafer made of semiconducting material such as silicon (Si). A layer of a silicon oxide is deposited on the wafer followed by a layer of silicon nitride on top of the oxide. The wafer is then coated with photoresist, exposed to the desired trench isolation pattern and the exposed photoresist is developed away. Nitride in the open areas is plasma etched away and followed by the oxide under the open areas stopping on the silicon. Then the silicon below the openings in the oxide and nitride is plasma etched to form a shallow trench space.

In step 320, a selective etch isolation material is deposited in the shallow trench space to form a selective etch shallow trench isolation barrier. The selective etch isolation material (e.g., nitride) etches differently than material contacting it. In one embodiment of the present invention, the selective etch isolation material is spread over the top of the remaining semiconducting material in a manner that causes the selective etch isolation material to fill the developed areas (e.g., the shallow trench space). After the developed areas are full of selective etch isolation material, excess selective etch isolation material is removed. In one embodiment of the present invention, the excess material is removed by a chemical mechanical polishing (CMP) process.

In step 330, an intermetal dielectric layer is fabricated on top of a device layer during an interlayer fabrication process. In one embodiment of selective etch material shallow trench isolation barrier integrated circuit chip fabrication process 300, the intermetal dielectric layer material includes oxide spread over the top to the device layer.

In Step 340, a contact hole is etched in the intermetal dielectric layer. In one embodiment of the present invention, a resistive mask pattern is created over the intermetal dielectric layer. The resist material is used to mask or protect one area of the wafer while working on another. In one embodiment the mask is imprinted utilizing a lithography. For example, in a photomasking process a photo resist or light-sensitive film is applied to the wafer, giving it characteristics similar to a piece of photographic paper. A photo aligner aligns the wafer to a mask and then projects an intense light through the mask and through a series of reducing lenses, thereby exposing the photo resist to light according to the mask pattern. The portions of the resist exposed to light becomes soft or hard depending on the photo resist used. The underlying intermetal dielectric layer is etched away to create a contact hole. In one embodiment the etching is accomplished by exposing the intermetal dielectric layer (e.g., an oxide layer) to a chemical solution or plasma gas discharge (e.g., Ar, CF₄, CHF₃, CO, and/or C₄F₈). The etching process stops on the selective etch isolation material of the selective etch shallow trench isolation barrier.

In step 350 the contact hole is filled with conductive material to form a contact plug. In one embodiment of selective etch material shallow trench isolation barrier integrated circuit chip fabrication process 300, the contact plug is formed by depositing tungsten or other conductor in the contact hole. In one embodiment of the present invention, the conductive material is spread over the top of the insulation material to fill the etched contact hole to form the contact plug. After the developed areas (e.g., a contact plug) are full of conductive material, excess material on top is removed (e.g., in a CMP process).

In one embodiment of selective etch material shallow trench isolation barrier integrated circuit chip fabrication process 300 other integrated electrical circuit components are included in a device layer comprising a selective etch shallow trench isolation barrier. For example, integrated electrical circuit elements are added through a process of masking, etching and doping of the diffusion material with additional chemicals. In one embodiment the present invention is implemented in a densely packed integrated circuit.

Thus, a selective etch shallow trench isolation barrier integrated circuit chip fabrication system and method of the present invention facilitates construction of a shallow trench isolation barrier without a shallow trench isolation barrier etch stop layer. A selective etch shallow trench isolation barrier of the present invention includes strong dielectric characteristics that assist the isolation of adverse influences from impacting electrical charges in an integrated circuit component. By fabricating a selective etch shallow trench isolation barrier in an integrated circuit without a shallow trench isolation barrier etch stop layer the present invention reduces the resources and time expending in fabricating an integrated circuit chip. The present invention also eliminates problems (e.g., etch stop, contamination, manufacturing errors, etc.) caused by a shallow trench isolation barrier etch stop layer. Furthermore, the present invention facilitates the compaction of devices in an advanced integrated circuit design.

The foregoing descriptions of specific embodiments of the present invention have been presented for purposes of illustration and description. They are not intended to be exhaustive or to limit the invention to the precise forms disclosed, and obviously many modifications and variations are possible in light of the above teaching. The embodiments were chosen and described in order to best explain the principles of the invention and its practical application, to thereby enable others skilled in the art to best utilize the invention and various embodiments with various modifications as are suited to the particular use contemplated. It is intended that the scope of the invention be defined by the claims appended hereto and their equivalents.

1-9. (Cancelled)

10. A selective etch shallow trench isolation barrier Integrated circuit chip fabrication process comprising the steps of:
forming a shallow trench space in a wafer;
depositing a selective etch isolation material in the shallow trench space to fill the shallow trench space and to form a selective etch shallow trench isolation barrier;
fabricating an intermetal dielectric layer on the wafer such that the intermetal dielectric layer is disposed in direct contact with the selective etch isolation material in the shallow trench space;
etching a contact hole in said intermetal dielectric layer down to said selective etch shallow trench isolation barrier such that at least a portion of the selective etch isolation material is exposed; and
filling said contact hole with conductive material;
wherein the selective etch isolation material and the intermetal dielectric layer are formed of different materials having different etch characteristics, such that the selective etch isolation material may be exposed to the intermetal dielectric layer etching without having any significant amount of the selective etch isolation material etched away.

11. The selective etch shallow trench isolation barrier integrated circuit chip fabrication process of claim 10 in which said etching of said contact hole in said intermetal layer down to said selective etch shallow trench isolation barrier is a single film layer etch step stopping on selective etch isolation material of said selective etch shallow trench isolation barrier.

12. The selective etch shallow trench isolation barrier integrated circuit chip fabrication process of claim 11 in which said intermetal dielectric layer comprises oxide and said single film layer etch step is performed by Ar, CF₄, CHF₃, CO, and/or C₄F₈.

13. (Cancelled)

14. The selective etch shallow trench isolation barrier integrated circuit chip fabrication process of claim 10 wherein said selective etch isolation material includes silicon nitride or oxynitride.

15. The selective etch shallow trench isolation barrier integrated circuit chip fabrication process of claim 10 further comprising the steps of:
depositing the selective etch isolation material to fill said shallow trench; and
removing excess selective etch isolation material by a chemical mechanical polishing (CMP) process.

16. The selective etch shallow trench isolation barrier integrated circuit chip fabrication process of claim 10 further comprising the steps of:
pre-cleaning a wafer using high purity, low particle chemicals;
heating said wafer;
exposing said wafer to ultra-pure oxygen in a diffusion furnace under carefully controlled conditions; and
forming a silicon dioxide film of uniform thickness on the surface of the wafer.

17. A selective etch shallow trench isolation barrier integrated circuit chip fabrication process comprising the steps of:
applying layers of oxide and nitride to a wafer;
creating a resistive mask pattern;
etching a shallow trench space;
depositing a selective etch isolation material in said shallow trench space to fill the shallow trench space and to form a selective etch shallow trench isolation barrier;
fabricating an intermetal dielectric layer on the wafer such that the intermetal dielectric layer is disposed in direct contact with the selective etch isolation material in the shallow trench space;
etching a contact hole in said intermetal dielectric layer down to said selective etch shallow trench isolation barrier such that at least a portion of the selective etch isolation material is exposed; and
filling said contact hole with conductive material;
wherein the selective etch isolation material and the intermetal dielectric layer are formed of different materials having different etch characteristics, such that the selective etch isolation material may be exposed to the intermetal dielectric layer etching without having any significant amount of the selective etch isolation material etched away.

18. The selective etch shallow trench isolation barrier integrated circuit chip fabrication process of claim 17 in which said etching of said contact hole in said intermetal dielectric layer down to said selective etch shallow trench isolation barrier is a single film layer etch step stopping on selective etch isolation material of said the selective etch shallow trench isolation barrier.

19. (Cancelled)

20. The selective etch shallow trench isolation barrier integrated circuit chip fabrication process of claim 17 wherein said selective etch isolation material includes silicon nitride or oxynitride.
